(19) United States
(12) Patent Application Publication
(10) Pub. No.: US 2025/0374487 A1
(43) Pub. Date: Dec. 4, 2025

(54) ELECTRICAL CONNECTION UNIT

(71) Applicant: YAZAKI CORPORATION, Tokyo (JP)

(72) Inventors: Ryu Senoo, Kakegawa-shi (JP); Hirotaka Mukasa, Kakegawa-shi (JP); Hirokuni Kurashiki, Susono-shi (JP)

(21) Appl. No.: 19/215,332

(22) Filed: May 22, 2025

(30) Foreign Application Priority Data
May 29, 2024 (JP) 2024-087308

(51) Int. Cl. H05K 7/20

(52) U.S. Cl. CPC H05K 7/2039

(57) ABSTRACT

An electrical connection unit includes an electronic component, a heat dissipation member, a first conductive member, a second conductive member, a fastening member, and a heat transfer member. The heat dissipation member is separated from the electronic component in a first direction. The first conductive member is electrically connected to the electronic component. The second conductive member has a connection portion. The connection portion is disposed between the first conductive member and the heat dissipation member in the first direction. The fastening member includes a head and a shaft. The head is disposed between the connection portion and the heat dissipation member in the first direction. The shaft penetrates the connection portion in the first direction and reaches the first conductive member. The heat transfer member is disposed between the head and the heat dissipation member in the first direction and is in contact with the head.

### BACKGROUND OF THE INVENTION

### Field of the Invention

Embodiments of the present invention relate to an electrical connection unit.

Priority is claimed on Japanese Patent Application No. 2024-087308 filed in Japan on May 29, 2024, the content of which is incorporated herein by reference.

### Description of the Related Art

There is an electrical connection unit including a housing in which electronic components are stored. A bus bar and a heat storage material are held in the housing.

### SUMMARY OF THE INVENTION

Incidentally, a connection portion between bus bars or heat storage members generates heat when the resistance increases. It is desirable to install a heat transfer member in the connection portion to dissipate heat. However, a bolt has been inserted into a housing so far. Thus, a surface difference between the bus bar and the bolt head is large, a heat transfer member cannot be installed across the bolt and the bus bar, and the heat transfer performance is insufficient.

An embodiment provides an electrical connection unit capable of improving heat transfer performance.

An electrical connection unit according to an embodiment includes an electronic component, a heat dissipation member, a first conductive member, a second conductive member, a fastening member, and a heat transfer member. The heat dissipation member is separated from the electronic component in a first direction. The first conductive member is electrically connected to the electronic component. The second conductive member has a connection portion. The connection portion is disposed between at least a part of the first conductive member and the heat dissipation member in the first direction. The fastening member includes a head and a shaft. The head is disposed between the connection portion and the heat dissipation member in the first direction. The shaft penetrates the connection portion in the first direction and extends to reach the first conductive member. The heat transfer member of which at least a part thereof is disposed between the head and the heat dissipation member in the first direction and is in contact with the head. The heat transfer member transfers heat from the head toward the heat dissipation member.

According to one embodiment, heat transfer performance can be improved.

### BRIEF DESCRIPTION OF THE DRAWINGS

FIG. 1 is a cross-sectional view illustrating an electrical connection unit according to an embodiment;

FIG. 2 is a perspective view showing a main body of the embodiment;

FIG. 3 is a perspective view showing a subunit of the embodiment;

FIG. 4 is a partially exploded perspective view of the subunit of the embodiment;

FIG. 5 is a perspective view showing an electronic component and a connection component according to the embodiment;

FIG. 6 is a perspective view showing the electronic component and the connection component according to the embodiment;

FIG. 7 is a perspective view illustrating the connection component according to the embodiment;

FIG. 8 is a perspective view illustrating a routing board of the embodiment;

FIG. 9 is a partially exploded perspective view of the routing board according to the embodiment;

FIG. 10 is a plan view illustrating the routing board according to the embodiment;

FIG. 11 is a partially exploded perspective view of the electrical connection unit according to the embodiment;

FIG. 12 is a bottom view illustrating the routing board of the embodiment;

FIG. 13 is a cross-sectional view taken along line F13-F13 of a structure illustrated in FIG. 10;

FIG. 14 is an enlarged cross-sectional view of a fastening member that fastens the connection component and the bus bar according to the embodiment;

FIG. 15 is an enlarged cross-sectional view illustrating a modification example;

FIG. 16 is an enlarged cross-sectional view illustrating a modification example; and

FIG. 17 is an enlarged cross-sectional view illustrating a modification example.

### DETAILED DESCRIPTION OF THE INVENTION

Hereinafter, embodiments will be described with reference to the drawings. In the following description, constitutions having the same or similar functions are denoted by the same reference numbers. Redundant descriptions of these constitutions may be omitted. Note that the constitution described below does not limit the scope of the embodiment.

In the present disclosure, the terms are defined as follows. The term “connection” is not limited to a mechanical connection, and may include an electrical connection. That is, the term “connection” is not limited to a case where two elements that are connection targets are directly connected, and may include a case where two elements that are connection targets are connected with another element interposed therebetween. The term “accommodation” is not limited to a case where the entire component is accommodated, and may include a case where only a part of the component is accommodated (a state in which the remaining part of the component protrudes). The term “facing” indicates that virtual projection images of two target objects overlap each other when viewed from a specific direction. That is, the term “facing” is not limited to a case where two target objects directly face each other, and may include a case where two target objects face each other in a state in which another member exists between the two target objects. “Parallel”, “orthogonal”, or “the same” may include “substantially parallel”, “substantially orthogonal”, or “substantially the same”, respectively.

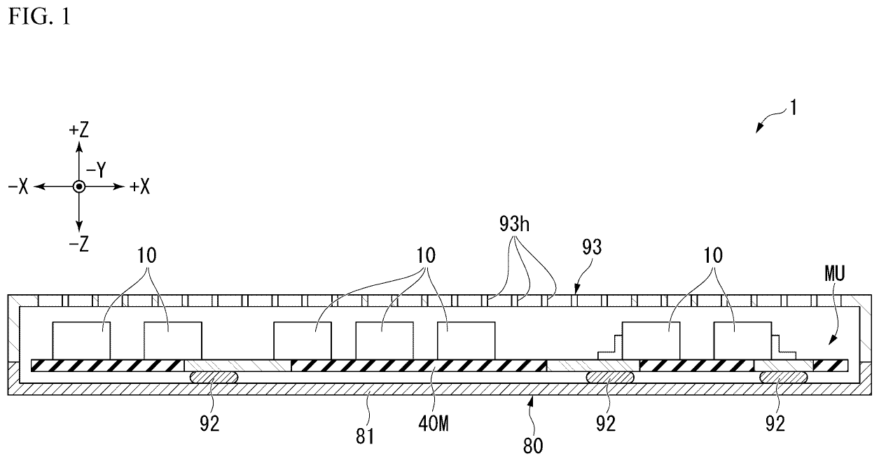

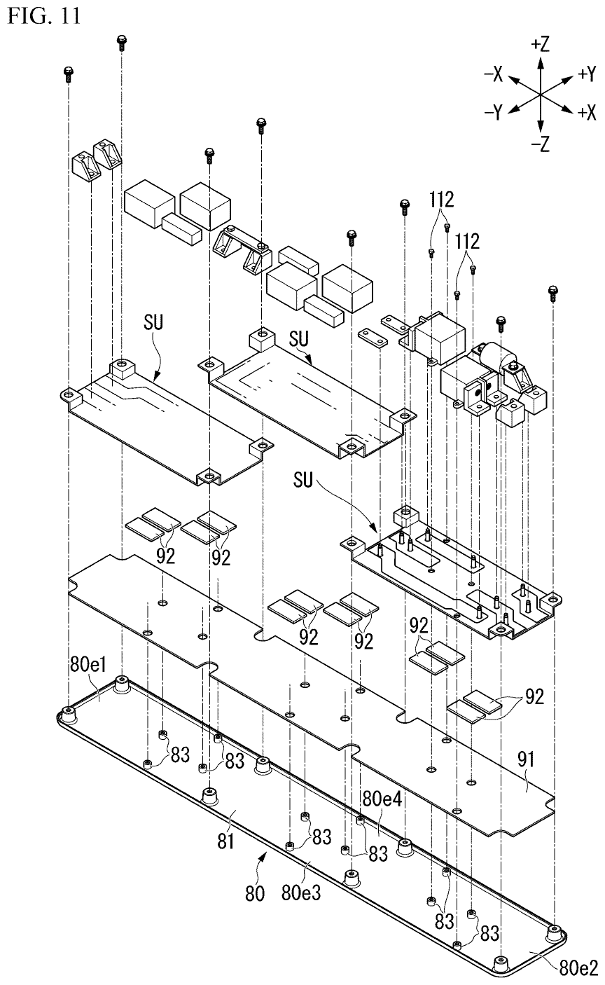

In the present disclosure, a +X direction, a −X direction, a +Y direction, a −Y direction, a +Z direction, and a −Z direction are defined as follows. The +X direction is a direction from a first end 80e1 to a second end 80e2 of a metal plate 80 that will be described later (see FIG. 11). The −X direction is a direction opposite to the +X direction. Hereinafter, in a case where the +X direction and the −X direction are not distinguished, the directions will be simply referred to as “X direction”. The +Y direction and the −Y direction are directions intersecting (for example, orthogonal to) the X direction. The +Y direction is a direction from a third end 80e3 to a fourth end 80e4 of the metal plate 80 that will be described later (see FIG. 11). The −Y direction is a direction opposite to the +Y direction. Hereinafter, in a case where the +Y direction and the −Y direction are not distinguished, the directions will be simply referred to as “Y direction”. The +Z direction and the −Z direction are directions intersecting (for example, orthogonal to) the X direction and the Y direction. The +Z direction is a direction from the metal plate 80 that will be described later toward a main body MU (see FIG. 1). The −Z direction is a direction opposite to the +Z direction. Hereinafter, in a case where the +Z direction and the −Z direction are not distinguished, the directions will be simply referred to as “Z direction”. The Z direction is an example of a “first direction”.

Hereinafter, in a case where the X direction and the Y direction are not distinguished, the directions may be referred to as “horizontal direction”. Hereinafter, the Z direction may be referred to as “vertical direction”. Hereinafter, the +Z direction side may be referred to as “upper”, and the −Z direction side may be referred to as “lower”. However, these expressions are expressions for convenience of description, and do not limit a gravity direction of an electrical connection unit 1 (an installation posture of the electrical connection unit 1).

### 1. Constitution of Electrical Connection Unit

FIG. 1 is a cross-sectional view schematically illustrating an electrical connection unit 1 according to an embodiment. The electrical connection unit 1 is, for example, an in-vehicle device mounted on a vehicle such as an electric vehicle (EV), a hybrid electric vehicle (HEV), or a plug-in hybrid electric vehicle (PHEV). The electrical connection unit 1 may be referred to as an “electrical connection box” or a “junction box”, for example. However, the electrical connection unit 1 is not limited to a box-shaped device.

The electrical connection unit 1 includes, for example, a main body MU, a metal plate 80, an insulating sheet 91 (see FIG. 11), a plurality of heat transfer members 92, and an insulating cover 93.

### 2. Main Body

First, the main body MU will be described.

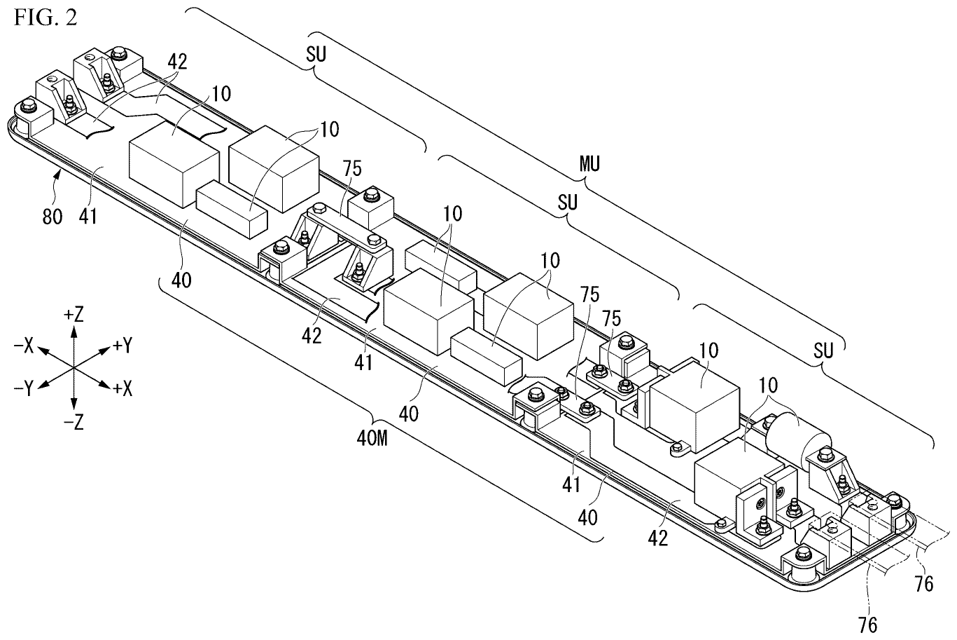

FIG. 2 is a perspective view showing the main body MU. The main body MU is a portion that performs a main function (for example, switching of electrical connection states or overcurrent protection) of the electrical connection unit 1. In the present embodiment, the main body MU is divided into a plurality of subunits SU. The main body MU is formed by connecting a plurality of subunits SU. In the present embodiment, the main body MU includes three subunits SU. Each subunit SU may be referred to as a “circuit constitution body”.

The three subunits SU have different electrical functions. Each subunit includes a plurality of electronic components 10 and a routing board 40. The plurality of electronic components 10 are electrically connected to the routing board 40.

In the present embodiment, the three subunits SU are disposed to be arranged in the X direction. For example, two subunits SU adjacent to each other in the X direction are electrically connected via a coupling bus bar 75. The coupling bus bar 75 is disposed on the side opposite to the metal plate 80 with respect to the plurality of subunits SU.

In the present embodiment, the three routing boards 40 are disposed on the same plane. In other words, the three routing boards 40 are disposed at the same height position in the Z direction. One large routing board 40M is formed by the three routing boards 40.

In the present embodiment, the three subunits SU have the same or similar basic structure. Therefore, one subunit SU will be described in detail below as a representative.

Note that the main body MU need not be divided into a plurality of subunits SU instead of the example described above. That is, the main body MU may be formed by the plurality of electronic components 10 and one routing board 40. In addition, the two or more subunits SU are not limited to the subunits SU having different functions, and may be the subunits SU having the same function.

### 3. Constitution of Subunit

Next, a constitution of the subunit SU will be described.

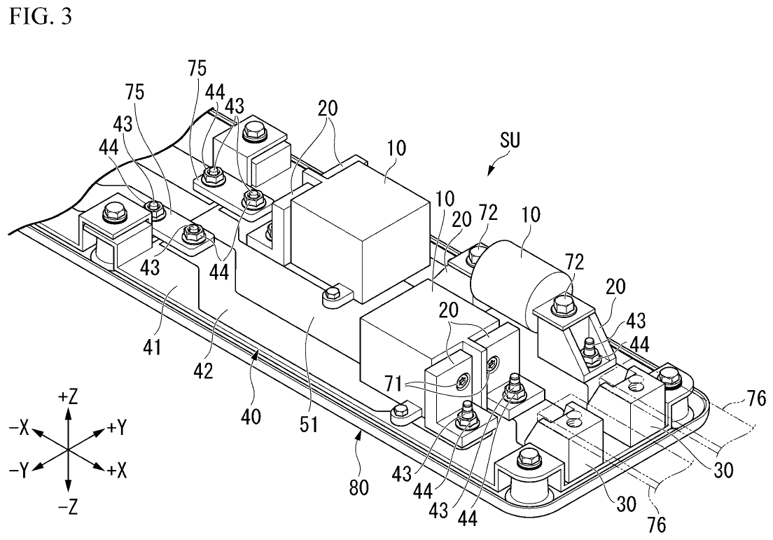

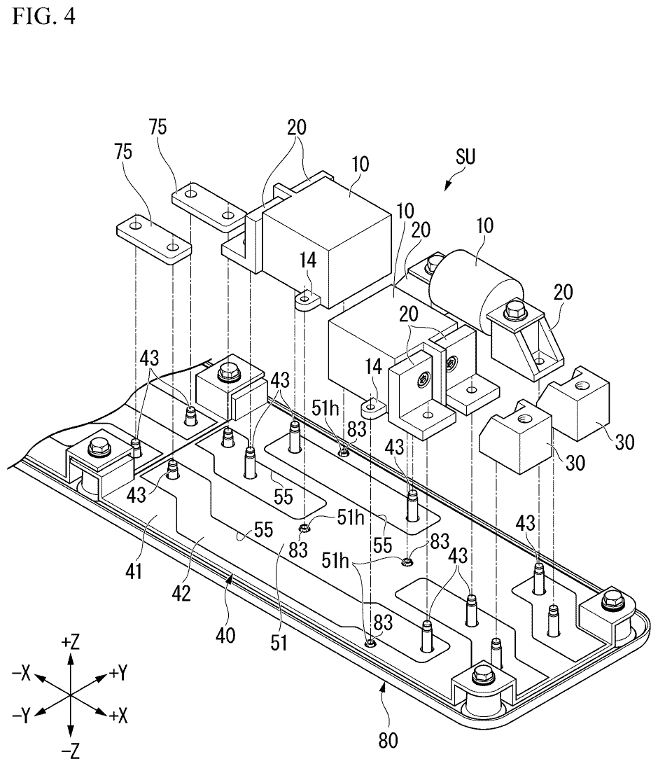

FIG. 3 is a perspective view showing the subunit SU. FIG. 4 is a partially exploded perspective view of the subunit SU. The subunit SU includes, for example, a plurality of electronic components 10, a plurality of connection components 20 for component connection, a plurality of connection components 30 for external connection, a routing board 40, a fastening member 43, and an engagement member 44. The connection components 20 and 30 are members forming an energization path in the vertical direction. The connection components 20 and 30 may be referred to as “vertical routing members”. The connection component 20 is an example of a “first conductive member”.

### 3.1 Electronic Component and Connection Component for Component Connection

First, the electronic component 10 and the connection component 20 for component connection will be described.

The electronic component 10 is an electronic component mounted according to a function required for the subunit SU. The electronic component 10 is, for example, a connector, a fuse, a relay (for example, a mechanical relay or a semiconductor relay), a capacitor, a branch component, any of various sensors (for example, a current sensor or a voltage sensor), an electronic control unit, or an electronic component unit in which two or more of these are unitized. Note that the type of the electronic component 10 is not limited to the above example. The electronic component 10 is, for example, a heat generating component that generates heat at the time of energization. Hereinafter, a first-type electronic component 10M and a second-type electronic component 10N will be described as examples of the electronic component 10.

The connection component 20 is a component that electrically connects the electronic component 10 to the routing board 40. The connection component 20 forms a part of an energization path in the subunit SU. The connection component 20 is made of a metal (for example, copper or a copper alloy). The connection component 20 may be referred to as a “metal component”. Hereinafter, a first-type connection component 20M and a second-type connection component 20N will be described as examples of the connection component 20.

### 3.1.1 First-Type Electronic Component

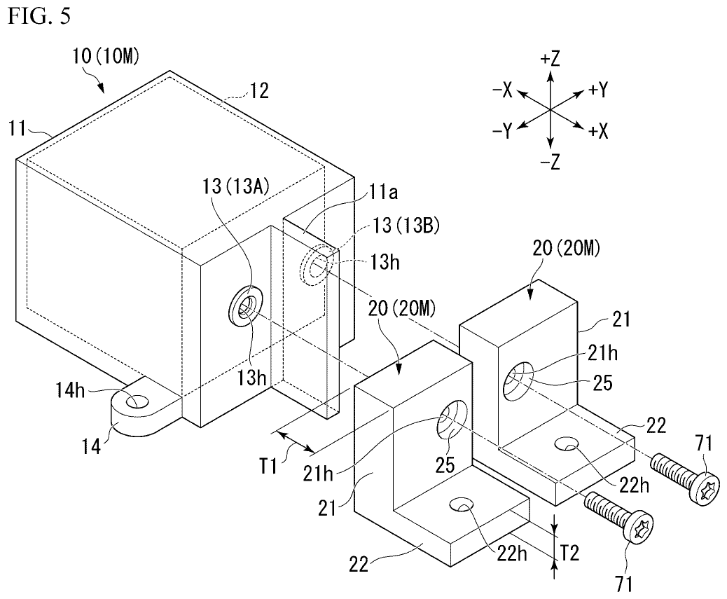

FIG. 5 is a perspective view illustrating the first-type electronic component 10M and the first-type connection component 20M. The first-type electronic component 10M is an electronic component in which a plurality of terminals 13 are disposed to be arranged at one end of the electronic component 10M. The electronic component 10M includes, for example, a case 11, a component body 12, a plurality of terminals 13, and a plurality of attachment portions 14.

### Case

The case 11 is an outer member that forms most of the outer shape of the electronic component 10M. The case 11 is made of, for example, synthetic resin and has an insulating property. The case 11 accommodates the component body 12. The case 11 and the component body 12 may be integrally formed.

In the present embodiment, the case 11 has an insulating rib 11a that protrudes in the horizontal direction (for example, the X direction) and extends in the Z direction. The insulating rib 11a has, for example, a plate shape formed in the horizontal direction (for example, the X direction) and the Z direction. The insulating rib 11a extends over the entire length of the case 11 in the Z direction, for example. The insulating rib 11a is disposed between the plurality of terminals 13 (a terminal 13A and a terminal 13B that will be described later). The insulating rib 11a electrically insulates the terminal 13A from the terminal 13B. In the present embodiment, a part of the insulating rib 11a is disposed between first portions 21 (that will be described later) of two connection components 20M connected to the electronic component 10M. The insulating rib 11a electrically insulates the first portions 21 of the two connection components 20M connected to the electronic component 10M from each other.

### Component Body

The component body 12 is a portion that performs a main function of the electronic component 10M. For example, in a case where the electronic component 10M is a relay, the component body 12 includes a switch (for example, a contact) that switches between a conductive state and a non-conductive state. For example, in a case where the electronic component 10M is a fuse, the component body 12 includes a fusion portion that is fused when an overcurrent flows. For example, in a case where the electronic component 10M is a capacitor, the component body 12 includes a portion that stores electric charge.

### Terminal

The terminal 13 is an electrical connection portion exposed to the outside of the case 11. The terminal 13 is electrically connected to the component body 12 inside the case 11. In the present embodiment, the electronic component 10M includes a terminal 13A and a terminal 13B as the plurality of terminals 13. One of the terminal 13A and the terminal 13B is a terminal on the positive electrode side. The other of the terminal 13A and the terminal 13B is a terminal on the negative electrode side.

In the present embodiment, the terminal 13A and the terminal 13B are provided at one end of the electronic component 10M in the horizontal direction (for example, the X direction). The terminal 13A and the terminal 13B are disposed to be arranged in the horizontal direction (for example, the Y direction). Each terminal 13 has an attachment hole 13h to which a fastening member 71 (for example, a screw or a bolt) that will be described later is attached. The attachment hole 13h is open in the horizontal direction (for example, the X direction). An inner circumferential surface of the attachment hole 13h of the electronic component 10M has a screw groove.

### Attachment Portion

The attachment portion 14 is a portion for fixing the electronic component 10M. The attachment portion 14 has an attachment hole 14h to which a fastening member 112 (for example, a screw or a bolt; and see FIG. 11) that will be described later is attached. The attachment hole 14h is open in the Z direction. The attachment hole 14h is an insertion hole through which the fastening member 112 passes. The attachment portion 14 is directly fixed to the metal plate 80 via the fastening member 112.

### 3.1.2 First-Type Connection Component

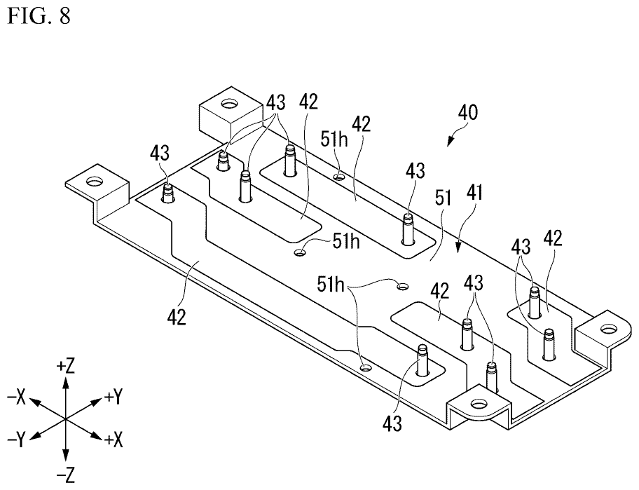

The first-type connection component 20M is a component that electrically connects the first-type electronic component 10M to the routing board 40. In the present embodiment, the connection component 20M electrically connects the electronic component 10M to a bus bar 42 (see FIG. 8) included in the routing board 40. In the present embodiment, the width of the connection component 20M in the longitudinal direction (for example, the X direction) of the electronic component 10M is smaller than the width of the electronic component 10M in the longitudinal direction. The connection component 20M includes, for example, a first portion 21 and a second portion 22.

### First Portion

The first portion 21 of the connection component 20M is a portion connected to the terminal 13 of the electronic component 10M. The first portion 21 is a plate-shaped or rectangular parallelepiped portion extending in the Z direction. The first portion 21 extends in the Z direction along one end (for example, an end in the X direction) of the electronic component 10M. The first portion 21 is a standing portion that stands in the Z direction with respect to the routing board 40 (for example, with respect to a bus bar 42 that will be described later). The first portion 21 is adjacent to the electronic component 10M in the horizontal direction (for example, the X direction). For example, the first portion 21 is adjacent to the terminal 13 of the electronic component 10M in the horizontal direction (for example, the X direction), and is connected to the terminal 13 of the electronic component 10M from the horizontal direction (for example, the X direction).

The first portion 21 of the connection component 20M has a first attachment hole 21h through which the fastening member 71 (for example, a screw or a bolt) passes. The first attachment hole 21h is open in the horizontal direction (for example, the X direction). The first portion 21 has a recess 25 around the first attachment hole 21h. The recess 25 is an accommodation portion that accommodates a head of the fastening member 71 inserted into the first attachment hole 21h. The fastening member 71 that has passed through the first attachment hole 21h is engaged with the attachment hole 13h of the terminal 13 of the electronic component 10M, and thus first portion 21 is physically and electrically connected to the terminal 13 of the electronic component 10M. The first portion 21 need not have the recess 25.

### Second Portion

The second portion 22 of the connection component 20M is a portion connected to the bus bar 42 (see FIG. 8). The second portion 22 protrudes in the horizontal direction (for example, the X direction) from end of the first portion 21 on the −Z direction side. The second portion 22 is a plate portion provided in the horizontal direction. The second portion 22 is adjacent to the bus bar 42 in the Z direction, and is connected to the bus bar 42 from the Z direction. The second portion 22 of the connection component 20M is attached from the Z direction to a fastening member 43 (for example, a screw or a bolt; and see FIG. 8), which will be described later, protruding from the bus bar 42 in the +Z direction, and is physically and electrically connected to the bus bar 42. In the present embodiment, the second portion 22 of the connection component 20M has a second attachment hole 22h through which the fastening member 43 passes. The second attachment hole 22h is open in the Z direction. In the second portion 22, the fastening member 43 passes through the second attachment hole 22h. An engagement member 44 (for example, a nut; and see FIG. 3) that will be described later is engaged with the tip of the fastening member 43 that has passed through the second attachment hole 22h, and thus the second portion 22 is fixed to the bus bar 42. In the present embodiment, the first portion 21 and the second portion 22 form one L-shaped connection component 20M.

### 3.1.3 Second-Type Electronic Component

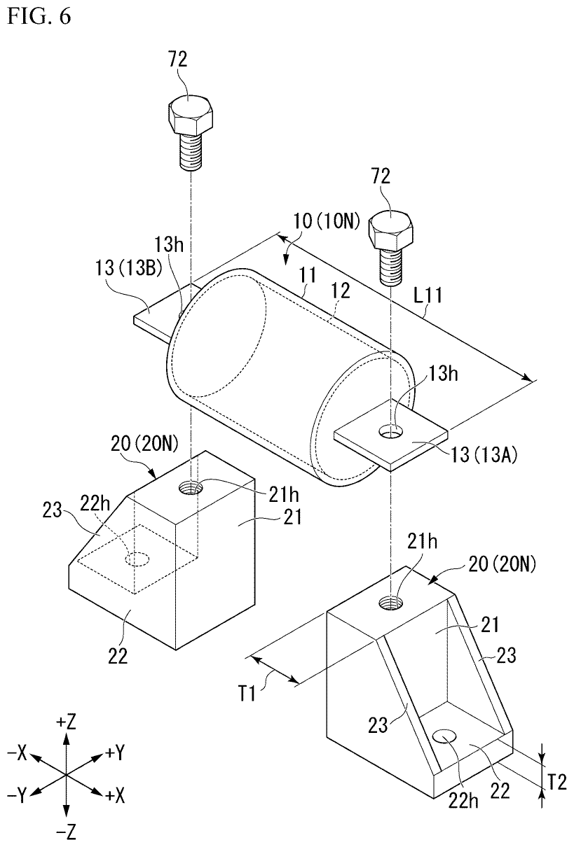

FIG. 6 is a perspective view illustrating the second-type electronic component 10N and the second-type connection component 20N. The second-type electronic component 10N is an electronic component in which two terminals 13 are separately disposed at both ends in the horizontal direction of the electronic component 10N. The electronic component 10N includes, for example, a case 11, a component body 12, and a plurality of terminals 13. Note that, among the constitutions of the electronic component 10N, constitutions having functions similar to those of the electronic component 10M are denoted by the same reference numbers. In this case, in the description regarding the electronic component 10N, the “electronic component 10M” may be replaced with the “electronic component 10N” in the description regarding the electronic component 10M described above.

In the electronic component 10N, the terminal 13A and the terminal 13B are disposed separately at both ends of the electronic component 10N in the horizontal direction (for example, the X direction). Each terminal 13 has an attachment hole 13h to which the fastening member 72 (for example, a screw or a bolt) is attached. The attachment hole 13h is open in the Z direction. For example, the attachment hole 13h of the electronic component 10N is an insertion hole through which the fastening member 72 passes.

### 3.1.4 Second-Type Connection Component

The second-type connection component 20N is a component that electrically connects the second-type electronic component 10N to the routing board 40. In the present embodiment, the connection component 20N electrically connects the electronic component 10N to the bus bar 42 (see FIG. 8) included in the routing board 40. In the present embodiment, a width of the connection component 20N in the longitudinal direction (for example, the X direction) of the electronic component 10N is smaller than a width of the electronic component 10N in the longitudinal direction. The connection component 20N includes, for example, a first portion 21, a second portion 22, and a third portion 23.

### First Portion

The first portion 21 of the connection component 20N is a portion connected to the terminal 13 of the electronic component 10N. The first portion 21 is a rectangular parallelepiped portion extending in the Z direction. The first portion 21 is a standing portion that stands in the Z direction with respect to the routing board 40 (for example, with respect to the bus bar 42). The first portion 21 is adjacent to the terminal 13 of the electronic component 10N in the Z direction, and is connected to the terminal 13 of the electronic component 10N from the Z direction. The first portion 21 of the connection component 20N has a first attachment hole 21h with which the fastening member 72 is engaged. The first attachment hole 21h is open in the Z direction. An inner circumferential surface of the first attachment hole 21h of the connection component 20N has a screw groove. The fastening member 72 that has passed through the attachment hole 13h of the terminal 13 of the electronic component 10N is engaged with the first attachment hole 21h of the first portion 21, and thus the first portion 21 is physically and electrically connected to the terminal 13 of the electronic component 10N.

### Second Portion

The second portion 22 of the connection component 20N is a portion connected to the bus bar 42 (see FIG. 8). The second portion 22 protrudes in the horizontal direction (for example, the X direction) from end of the first portion 21 on the −Z direction side. The second portion 22 is a plate portion provided in the horizontal direction. The second portion 22 is adjacent to the bus bar 42 in the Z direction, and is connected to the bus bar 42 from the Z direction. The second portion 22 of the connection component 20N is attached to, from the Z direction, the fastening member 43 (for example, a screw or a bolt; and see FIG. 8) protruding from the bus bar 42 in the +Z direction, and is physically and electrically connected to the bus bar 42. In the present embodiment, the second portion 22 of the connection component 20N has a second attachment hole 22h through which the fastening member 43 passes. The second attachment hole 22h is open in the Z direction. In the second portion 22, the fastening member 43 that will be described later passes through the second attachment hole 22h. An engagement member 44 (for example, a nut; and see FIG. 3) is engaged with the tip of the fastening member 43 that has passed through the second attachment hole 22h, and thus the second portion 22 is fixed to the bus bar 42.

### Third Portion

The third portion 23 is a standing wall (side wall) standing in the +Z direction from both ends of the second portion 22 in the horizontal direction. The third portion 23 is a wall provided in the Z direction. The third portion 23 is connected to the first portion 21 and is also connected to the second portion 22. For example, the third portion 23 extends obliquely so as to increase in the X direction as it advances in the −Z direction. The third portion 23 may be provided in the connection component 20M described above. On the other hand, the connection component 20N need not have the third portion 23.

### 3.2 Connection Component for External Connection

Next, the connection component 30 for external connection will be described.

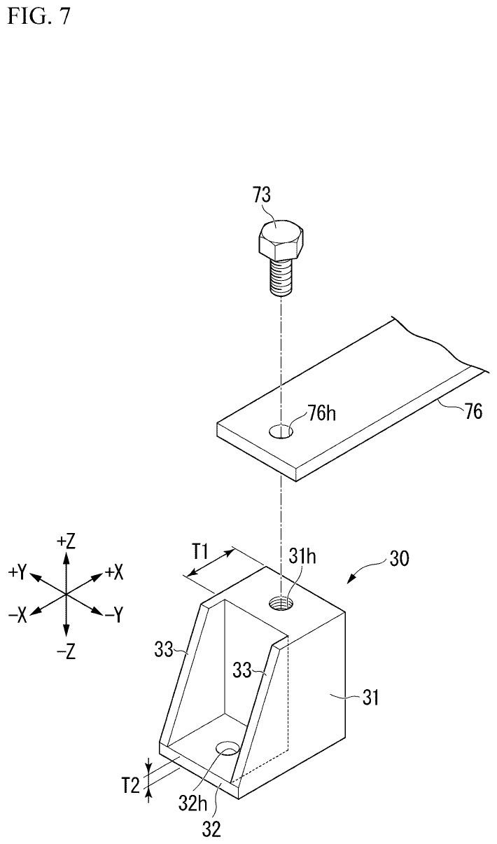

FIG. 7 is a perspective view illustrating the connection component 30 for external connection. The connection component 30 is a component that electrically connects an external coupling bus bar 76 to the routing board 40. In the present embodiment, the connection component 30 electrically connects the external coupling bus bar 76 to the bus bar 42 (see FIG. 8) included in the routing board 40. The external coupling bus bar 76 is electrically connected to an external device. In the present disclosure, the “external device” is an electrical device existing outside the electrical connection unit 1. The external device is, for example, a battery unit mounted on a vehicle or an inverter for driving a motor of the vehicle, but is not limited to these examples. The connection component 30 includes, for example, a first portion 31, a second portion 32, and a third portion 33.

### First Portion

The first portion 31 is a portion connected to the external coupling bus bar 76. The first portion 31 is a rectangular parallelepiped portion extending in the Z direction. The first portion 31 is a standing portion that stands in the Z direction with respect to the routing board 40 (for example, with respect to the bus bar 42). The first portion 31 is adjacent to the external coupling bus bar 76 in the Z direction, and is connected to the external coupling bus bar 76 from the Z direction. The first portion 31 has a first attachment hole 31h through which a fastening member 73 (for example, a screw or a bolt) passes. The first attachment hole 31h is open in the Z direction. An inner circumferential surface of the first attachment hole 31h has a screw groove. The fastening member 73 that has passed through the attachment hole 76h of the external connection bus bar 76 is engaged with the first attachment hole 31h of the first portion 31, and thus the first portion 31 is physically and electrically connected to the external connection bus bar 76.

### Second Portion

The second portion 32 is a portion connected to the bus bar 42 (see FIG. 8). The second portion 32 protrudes in the horizontal direction (for example, the X direction) from the end of the first portion 31 on the −Z direction side. The second portion 32 is a plate portion provided in the horizontal direction. The second portion 32 is adjacent to the bus bar 42 in the Z direction, and is connected to the bus bar 42 from the Z direction. The second portion 32 is attached to, from the Z direction, the fastening member 43 (for example, a screw or a bolt; and see FIG. 8) protruding from the bus bar 42 in the +Z direction, and is physically and electrically connected to the bus bar 42. In the present embodiment, the second portion 32 has a second attachment hole 32h through which the fastening member 43 passes. The second attachment hole 32h is open in the Z direction. In the second portion 32, the fastening member 43 that will be described later passes through the second attachment hole 32h. The engagement member 44 (for example, a nut; and see FIG. 3) is engaged with the tip of the fastening member 43 that has passed through the second attachment hole 32h, and thus the second portion 32 is fixed to the bus bar 42.

### Third Portion

The third portion 33 is a standing wall (side wall) standing in the +Z direction from both ends of the second portion 32 in the horizontal direction. The third portion 33 is a wall provided in the Z direction. The third portion 33 is connected to the first portion 31 and is also connected to the second portion 32. For example, the third portion 33 extends obliquely to increase in the X direction (or the Y direction) as proceeding in the −Z direction. The connection component 30 need not include the third portion 33.

### 3.3 Routing Board

Next, the routing board 40 will be described.

FIG. 8 is a perspective view illustrating the routing board 40. The routing board 40 is a member that forms at least a part of an energization path between the plurality of electronic components 10 and/or at least a part of an energization path between the electronic component 10 and an external device. In the present disclosure, the “routing board” indicates a board-type routing structure. The “board type” indicates a plate shape along one plane when viewed as a whole regardless of a fine shape. In the present disclosure, the term “plate shape”, “sheet shape”, or “planar” is not limited to the case of being completely flat, and may include a case where a fixing structure, a rib, or the like protruding in the Z direction is partially present, a case where an uneven shape following the thickness of the bus bar is present on the surface, and the like. In the present embodiment, the routing board 40 has a plate shape formed in the X direction and the Y direction.

The routing board 40 includes, for example, a base plate 41 and one or more (for example, a plurality of) bus bars 42. In the present embodiment, the base plate 41 and the plurality of bus bars 42 are integrated through insert molding. For example, the routing board 40 is formed as a single member by insert-molding the bus bar 42 with the base plate 41 after the fastening member 43 is fixed to the bus bar 42. That is, the bus bar 42 is integrated with the base plate 41 without using a fastening member such as a screw or a bolt.

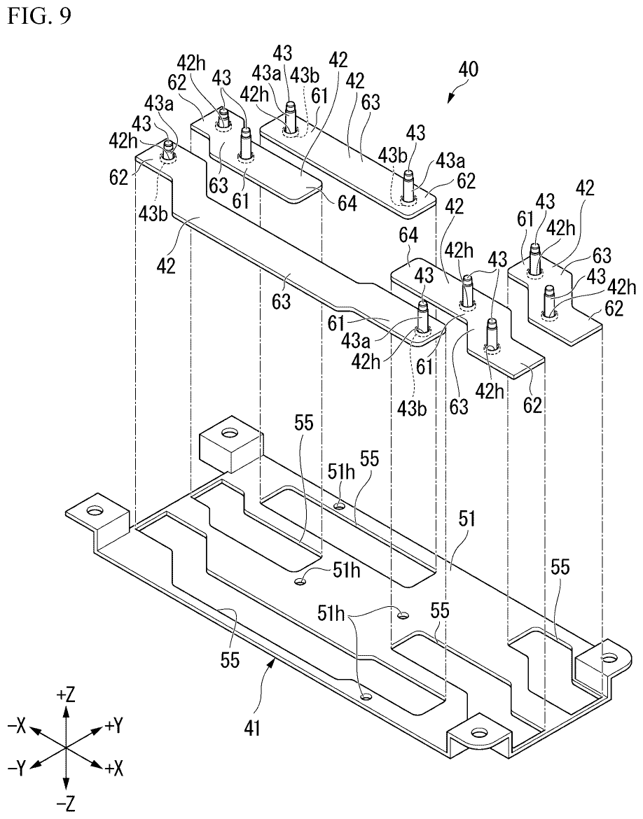

FIG. 9 is a partially exploded perspective view of the routing board 40. Hereinafter, for convenience of description, the base plate 41 and the bus bar 42 will be described with reference to the drawings in which the routing board 40 is partially exploded.

### Base Plate

The base plate 41 is a holding member that integrally holds the plurality of bus bars 42 arranged in the horizontal direction at intervals. The base plate 41 is made of, for example, synthetic resin and has an insulating property. The base plate 41 electrically insulates the plurality of bus bars 42 from each other. The base plate 41 may be referred to as an “insulating substrate”. The base plate 41 is fixed to the metal plate 80 via a fastening member such as a bolt or a screw. The base plate 41 has, for example, a flat surface portion 51.

The flat surface portion 51 is a portion formed in a plate shape in the base plate 41. The flat surface portion 51 has a plate shape formed in the horizontal direction. The flat surface portion 51 forms a main portion of the base plate 41. The flat surface portion 51 is a base portion (insulating base portion) of the base plate 41. In the present embodiment, the flat surface portion 51 extends over the entire width in the X direction of the base plate 41 and over the entire width in the Y direction of the base plate 41 except for four corner portions of the base plate 41. A thickness direction (plate thickness direction) of the flat surface portion 51 is the Z direction.

The flat surface portion 51 has a plurality of through-holes 51h into which fixing portions 83 (that will be described later) of the metal plate 80 are inserted. Furthermore, the flat surface portion 51 includes, for example, one or more (for example, a plurality of) accommodation portions 55 in which the bus bars 42 are accommodated, respectively. The plurality of accommodation portions 55 are formed apart from each other in the X direction or the Y direction. For example, five accommodation portions 55 are provided. Each of the accommodation portions 55 is, for example, a through-hole penetrating the flat surface portion 51 in the Z direction. Each accommodation portion 55 has an outer shape corresponding to the shape of the bus bar 42 to be accommodated when viewed from the Z direction. In the present disclosure, the phrase “the accommodation portion penetrates the flat surface portion in the first direction (Z direction)” may include a case where a part of the entire length of the accommodation portion 55 penetrates the flat surface portion 51 in the Z direction (for example, the remaining portion of the accommodation portion 55 may be a recess recessed in the Z direction, or may be provided inside the base plate 41 and not exposed to the outside of the base plate 41).

### Bus Bar

The bus bar 42 is a routing member (electrical connection member) included in the routing board 40. The bus bar 42 is, for example, a routing member for electrically connecting the plurality of electronic components 10. The bus bar 42 is an example of a “second conductive member”. Alternatively, the bus bar 42 may be a routing member for connecting the electronic component 10 to an external device. The bus bar 42 is made of a metal (for example, copper or a copper alloy) and has conductivity. In the present embodiment, the routing board 40 includes one bus bar 42 in each accommodation portion 55. That is, in the illustrated example, the routing board 40 includes, for example, a total of five bus bars 42. The five bus bars 42 are disposed to be arranged in the horizontal direction at intervals. The five bus bars 42 include portions disposed on the same plane. The five bus bars 42 are held by the flat surface portion 51 of the base plate 41.

At least a part of each bus bar 42 has a plate shape formed in the horizontal direction. At least a part of each bus bar 42 is accommodated in the accommodation portion 55 and extends along the flat surface portion 51. At least a part of each bus bar 42 extends in the horizontal direction in the accommodation portion 55. In the present embodiment, each bus bar 42 has a plate shape formed in the horizontal direction over the entire bus bar 42. Each of the bus bars 42 is accommodated in the accommodation portion 55 over the entire length of the bus bar 42 and extends along the flat surface portion 51. An upper surface of each bus bar 42 is exposed upward, and a lower surface of each bus bar 42 is exposed downward. The bus bar 42 is a member that forms a horizontal energization path. The bus bar 42 may be referred to as a “horizontal routing member”.

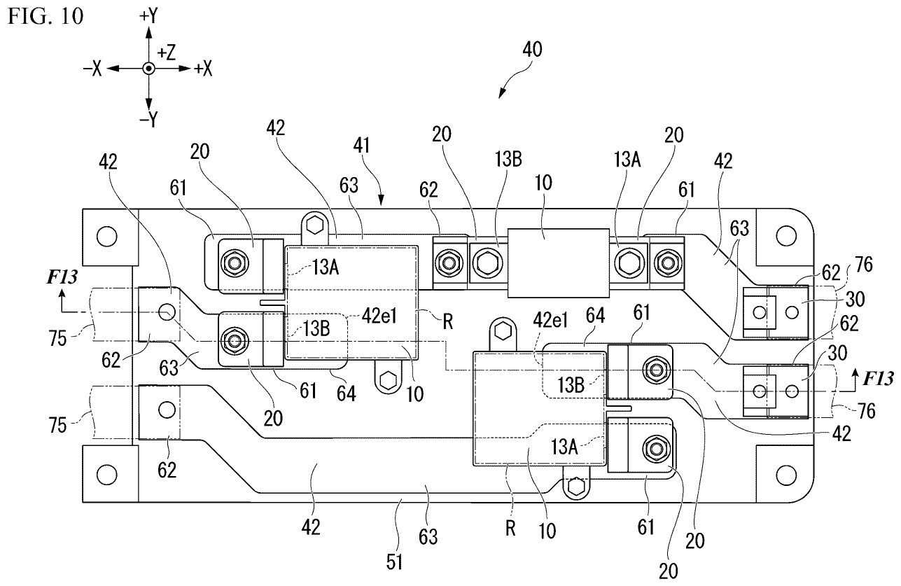

FIG. 10 is a plan view illustrating the routing board 40. Each bus bar 42 includes, for example, a first connection portion 61, a second connection portion 62, and an extending portion 63.

The first connection portion 61 is a portion in contact with one connection component 20 (hereinafter referred to as a “first connection component 20”). The first connection component 20 is a connection component that connects one electronic component 10 (hereinafter referred to as a “first electronic component 10”) to the bus bar 42. The first connection portion 61 is a portion of the bus bar 42 overlapping the first connection component 20 when viewed from the Z direction. The first connection portion 61 is disposed between the second portion 22 of the first connection component 20 and the metal plate 80 in the Z direction. The first connection portion 61 is an example of a “connection portion”. The first connection portion 61 is adjacent to the first connection component 20 in the Z direction, and is connected to the first connection component 20 from the Z direction.

The second connection portion 62 is a portion in contact with another connection component 20 (hereinafter referred to as a “second connection component 20”). The second connection component 20 is a connection component that connects another electronic component 10 (hereinafter referred to as a “second electronic component 10”) included in the plurality of electronic components 10 to the bus bar 42. The second connection portion 62 is a portion of the bus bar 42 overlapping the second connection component 20 when viewed from the Z direction. The second connection portion 62 is adjacent to the second connection component 20 in the Z direction, and is connected to the second connection component 20 from the Z direction.

Note that the second connection portion 62 may be a portion in contact with another connection component 30 (hereinafter referred to as a “second connection component 30”) instead of the above example. The connection component 30 is a connection component for connecting an external device to the bus bar 42. In this case, the second connection portion 62 is a portion of the bus bar 42 overlapping the second connection component 30 when viewed from the Z direction. The second connection portion 62 is adjacent to the second connection component 30 in the Z direction, and is connected to the second connection component 30 from the Z direction.

The second connection portion 62 may be a portion in contact with the coupling bus bar 75 for connection with another subunit SU instead of the connection components 20 and 30. In this case, the second connection portion 62 is a portion of the bus bar 42 that overlaps the coupling bus bar 75 when viewed from the Z direction. The second connection portion 62 is adjacent to the coupling bus bar 75 in the Z direction, and is connected to the coupling bus bar 75 from the Z direction.

The extending portion 63 extends from the first connection portion 61 in the X direction or the Y direction. The extending portion 63 is provided between the first connection portion 61 and the second connection portion 62. The extending portion 63 extends over the first connection portion 61 and the second connection portion 62. The extending portion 63 connects the first connection portion 61 to the second connection portion 62.

In the present embodiment, the first connection portion 61, the second connection portion 62, and the extending portion 63 have a plate shape formed in the horizontal direction. In the present embodiment, each bus bar 42 is accommodated in the accommodation portion 55 at least over the first connection portion 61 and the second connection portion 62 and extends along the flat surface portion 51. For example, the first connection portion 61, the second connection portion 62, and the extending portion 63 are accommodated in the accommodation portion 55 and extend along the flat surface portion 51.

In the present embodiment, the extending portions 63 of some of the bus bars 42 are accommodated in the accommodation portion 55 to extend over both sides of a region R through the region R overlapping the electronic component 10 when viewed from the Z direction. For example, the extending portion 63 extends linearly in the X direction. The extending portion 63 extends over a region R overlapping the electronic component 10 when viewed from the Z direction, over the +X direction side and the −X direction side of the region R. That is, the bus bar 42 is accommodated in the accommodation portion 55 to be easily routed through a better path (for example, a path with a shorter distance) without being disturbed by the presence of the electronic component 10.

The one or more bus bars 42 may have an extension 64 in addition to the first connection portion 61, the second connection portion 62, and the extending portion 63. The extension 64 is a portion where the bus bar 42 extends for the purpose of increasing a heat dissipation area and/or increasing a heat capacity for heat storage (heat absorption). The extension 64 is a portion that is not used for electrical connection. For example, the extension 64 is located on the side opposite to the extending portion 63 with respect to the first connection portion 61 (or the second connection portion 62). The extension 64 has a plate shape formed in the horizontal direction. The extension 64 is accommodated in the accommodation portion 55 and extends along the flat surface portion 51. The extension 64 extends to the region R overlapping the electronic component 10 when viewed from the Z direction, and has an end 42el of the bus bar 42 at a position overlapping the electronic component 10 when viewed from the Z direction.

### 3.4 Fastening Member and Engagement Member

Next, the fastening member 43 and the engagement member 44 (see FIG. 3) will be described. The fastening member 43 is a component for fixing the bus bar 42 and a connection target component (the connection component 20, the connection component 30, or the coupling bus bar 75) of the bus bar 42. Structures of the fastening member 43 and the engagement member 44 will be described in detail later.

### 4. Metal Plate, Insulating Sheet, Heat Transfer Member, and Insulating Cover

Next, the metal plate 80, the insulating sheet 91, the heat transfer member 92, and the insulating cover 93 will be described.

### 4.1 Metal Plate

FIG. 11 is a partially exploded perspective view of the electrical connection unit 1. The metal plate 80 ensures the rigidity of the electrical connection unit 1. The metal plate 80 is an example of a “heat dissipation member”, and enhances the heat dissipation property of the electrical connection unit 1. The metal plate 80 is made of a metal (for example, aluminum or an aluminum alloy). The metal plate 80 may be referred to as a “rigid member”.

The metal plate 80 has a rectangular shape formed in the X direction when viewed from the Z direction. The metal plate 80 has a first end 80e1, a second end 80e2, a third end 80e3, and a fourth end 80e4. The first end 80e1 and the second end 80e2 are a pair of ends of the metal plate 80 in the longitudinal direction, and are separated in the X direction. The third end 80e3 and the fourth end 80e4 are a pair of ends of the metal plate 80 in the lateral direction, and are separated in the Y direction. The metal plate 80 is separated from the electronic component 10 in the Z direction. The metal plate 80 includes, for example, a flat surface portion 81 and a plurality of fixing portions 83.

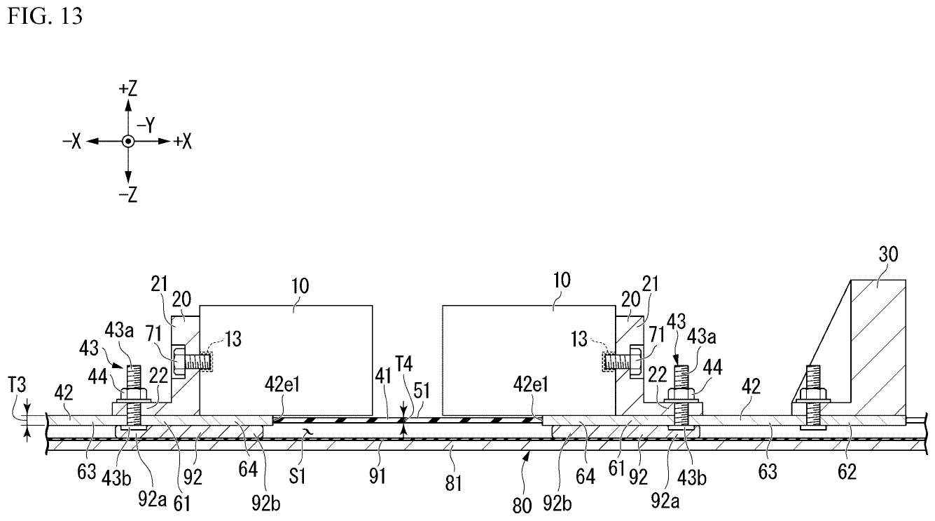

The flat surface portion 81 is a portion formed in a plate shape in the metal plate 80. The flat surface portion 81 has a plate shape formed in the horizontal direction. The flat surface portion 81 forms a main portion of the metal plate 80. The flat surface portion 81 is a base portion (metal base portion) of the metal plate 80. In the present embodiment, the flat surface portion 81 has a size that covers the three subunits SU from below. The flat surface portion 81 faces the routing boards 40 of the three subunits SU. In the present embodiment, the metal plate 80 is disposed with a gap S1 (see FIG. 13) between the metal plate 80 and the flat surface portion 51 of each subunit SU.

The fixing portion 83 is a fixing portion for directly fixing the electronic component 10 of each subunit SU to the metal plate 80 without interposing the base plate 41. The fixing portion 83 is inserted into the through-hole 51h of the flat surface portion 51 of the base plate 41. The fixing portion 83 is provided at a position corresponding to the attachment portion 14 of the electronic component 10 of each subunit SU when viewed from the Z direction. The fixing portion 83 is a cylindrical or prismatic boss protruding in the +Z direction from the flat surface portion 81. The attachment portion 14 of the electronic component 10 is fixed to the fixing portion 83 via a fastening member 112.

### 4.2 Insulating Sheet

The insulating sheet 91 is an insulating member for electrically insulating the metal plate 80 and the bus bar 42 of each subunit SU. The insulating sheet 91 is made of, for example, a synthetic resin such as polyester or polyimide, and has an insulating property. The insulating sheet 91 has a rectangular shape when viewed from the Z direction. The insulating sheet 91 has a sheet shape formed in the horizontal direction. The insulating sheet 91 is disposed between the flat surface portion 81 of the metal plate 80 and the routing board 40 of each subunit SU. For example, the insulating sheet 91 is disposed between the flat surface portion 81 of the metal plate 80 and the plurality of heat transfer members 92.

In the present embodiment, the insulating sheet 91 is attached to the flat surface portion 81 of the metal plate 80. The insulating sheet 91 has a notch or an opening for avoiding a portion protruding in the +Z direction, such as the fixing portion 83 of the metal plate 80. Note that, instead of the above example, the insulating sheet 91 may be provided between the routing board 40 of each subunit SU and the plurality of heat transfer members 92. Note that, in a case where the heat transfer member 92 has an insulating property and the necessary insulating property is secured by the heat transfer member 92, the insulating sheet 91 may be omitted.

### 4.3 Heat Transfer Member

The heat transfer member 92 is a member for transferring heat generated by the electronic component 10 at the time of energization and/or heat (Joule heat) generated by the bus bar 42 itself at the time of energization to the metal plate 80. The heat transfer member 92 is, for example, a heat transfer sheet (for example, a thermally conductive silicone sheet) having elasticity. The heat transfer member 92 is made of a material having higher thermal conductivity than that of the base plate 41, for example. However, the heat transfer member 92 is not limited to the above example, and may be a heat transfer member made of a thermally conductive gel or another material.

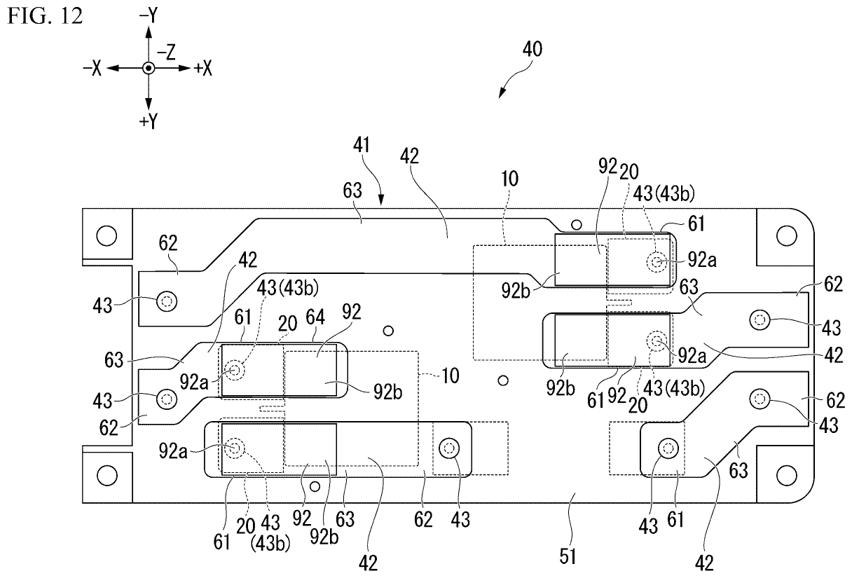

FIG. 12 is a bottom view illustrating the routing board 40. In the present embodiment, the plurality of heat transfer members 92 are partially provided in the routing board 40. The heat transfer member 92 is attached to the lower surface of each bus bar 42. The width (for example, the width in the Y direction) of the heat transfer member 92 is designed to be slightly smaller than the width (for example, the width in the Y direction) of the corresponding bus bar 42. The disposition of the heat transfer member 92 will be described in detail later.

### 4.4 Insulating Cover

Referring to FIG. 1 again, the insulating cover 93 will be described. The insulating cover 93 is a member for preventing the main body MU from contacting the energization path. The insulating cover 93 is made of, for example, a synthetic resin and has an insulating property. The insulating cover 93 has, for example, a box shape that is open on the −Z direction side. The insulating cover 93 has a plurality of vent holes 93h. The insulating cover 93 is attached to the metal plate 80 in the Z direction. Note that the insulating cover 93 is not limited to a box-shaped member, and may be a sheet-shaped member that covers the energization path of the main body MU.

### 5. Structure Related to Connection Component

Referring to FIG. 3 again, a structure related to the connection component 20 will be described.

In the present embodiment, the connection components 20 (for example, the connection component 20M and the connection component 20N) are heat storage members (heat absorbing members) that increase the heat capacity of the energization path of the electrical connection unit 1. The connection component 20 stores (absorbs) at least a part of heat generated by the electronic component 10, for example. Alternatively/additionally, the connection component 20 may store (absorb) at least a part of heat generated by the bus bar 42 itself due to energization. The connection component 20 may be referred to as a “heat storage component” or a “heat absorbing component”.

FIG. 13 is a cross-sectional view taken along line F13-F13 of the structure illustrated in FIG. 10.

In the present embodiment, the bus bar 42 is disposed at a position away from the terminal 13 of the electronic component 10 (for example, a position away in the Z direction). The connection component 20 is disposed between the electronic component 10 and the bus bar 42. In the present disclosure, the phrase “the connection component is disposed between the electronic component and the bus bar” is not limited to a case where a part of the connection component is located between the electronic component and the bus bar when viewed from the X direction or the Y direction. The phrase “the connection component is disposed between the electronic component and the bus bar” may correspond to a case where a part of the connection component is located between the electronic component and the bus bar when viewed from a direction inclined with respect to the X direction or the Y direction. The connection component 20 electrically connects the terminal 13 of the electronic component 10 to the bus bar 42.

Referring to FIGS. 5 and 6 again, in the present embodiment, the thickness of at least a part of the connection component 20 is larger than the plate thickness (thickness in the Z direction) T3 of the bus bar 42. For example, a thickness T1 of at least a part of the connection component 20 in the X direction is larger than the plate thickness T3 of the bus bar 42. In the present embodiment, the thickness T1 of the first portion 21 of the connection component 20 in the X direction is larger than the plate thickness T3 of the bus bar 42. In the present embodiment, the first portion 21 has the thickness T1 larger than the plate thickness T3 of the bus bar 42 as a thickness in the X direction over the entire length of the first portion 21 in the Z direction. The thickness T1 of the first portion 21 of the connection component 20 in the X direction is, for example, twice or more the plate thickness T3 of the bus bar 42. From another point of view, a thickness T2 of the second portion 22 of the connection component 20 in the Z direction may be larger than the plate thickness T3 of the bus bar 42.

In the present embodiment, the thickness T1 of the first portion 21 of the connection component 20 in the X direction is larger than the thickness T2 of the second portion 22 of the connection component 20 in the Z direction. In the present embodiment, the first portion 21 has the thickness T1 larger than the thickness T2 of the second portion 22 in the Z direction as a thickness in the X direction over the entire length of the first portion 21 in the Z direction.

The dimensional relationship described above is the same for the connection component 30 to which the external connection bus bar 76 is connected. For example, in the description of the connection component 30, the “connection component 20” may be replaced with the “connection component 30”, the “first portion 21” may be replaced with the “first portion 31”, and the “second portion 22” may be replaced with the “second portion 32” in the description of the connection component 20.

### 6. Structure Related to Bus Bar

Next, referring to FIG. 13 again, a structure related to the bus bar 42 will be described. The bus bar 42 is formed to be slightly thicker than the base plate 41. That is, the plate thickness T3 of the bus bar 42 in the Z direction is larger than a plate thickness T4 of the base plate 41 in the Z direction. The upper surface of the bus bar 42 is located slightly above the upper surface of the base plate 41, and the lower surface of the bus bar 42 is located slightly below the lower surface of the base plate 41. In the illustrated example, the connection components 20 and 30 and the electronic component 10 are placed on the bus bar 42 and are disposed with a slight gap from the base plate 41. The plate thickness T3 of the bus bar 42 in the Z direction may be equal to the plate thickness T4 of the base plate 41 in the Z direction, and the upper surface of the bus bar 42 may be located on the same plane as the upper surface of the base plate 41, or the lower surface of the bus bar 42 may be located on the same plane as the lower surface of the base plate.

### 7. Fastening Member and Structure around Fastening Member

Next, the fastening member 43 and a structure around the fastening member 43 will be described. Hereinafter, the fastening member 43 for fastening the first-type connection component 20M and the bus bar 42 will be described as an example of the fastening member 43 and a structure around the fastening member 43.

The fastening member 43 is a component for fixing the bus bar 42 and a connection target component (the connection component 20, the connection component 30, or the coupling bus bar 75) of the bus bar 42. The fastening member 43 is, for example, a caulking bolt fixed to the bus bar 42.

In the present embodiment, each of the first connection portion 61 and the second connection portion 62 of the bus bar 42 has a through-hole 42h. The through-hole 42h penetrates the bus bar 42 in the Z direction. The fastening member 43 is, for example, a bolt having a shaft 43a and a head 43b.

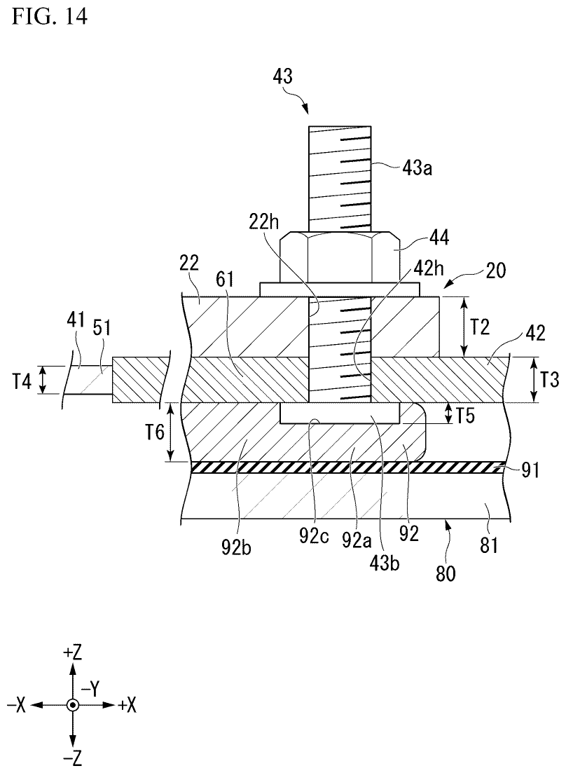

FIG. 14 is an enlarged cross-sectional view of the fastening member 43 that fastens the connection component 20 and the bus bar 42 according to the embodiment.

The shaft 43a penetrates the first connection portion 61 in the Z direction and reaches the second portion 22 of the connection component 20. A circumferential surface of the shaft 43a has a screw groove. The head 43b is disposed between the first connection portion 61 of the bus bar 42 and the metal plate 80 in the Z direction. The head 43b of the fastening member 43 is caulked and fixed to the bus bar 42 in a state in which the shaft 43a passes through the through-hole 42h of the bus bar 42. With this fixation, the fastening member 43 is electrically and physically connected to the bus bar 42 in a state in which the shaft 43a protrudes in the +Z direction from the through-hole 42h of the bus bar 42.

The head 43b is formed in a disk shape of which a central axis extends in the Z direction and that extends in the XY direction. The diameter of the head 43b is larger than the diameter of the shaft 43a. A shape of the head 43b can be changed as appropriate. The head 43b may be formed in, for example, a polygonal plate shape. However, a shape of the head 43b is preferably a disk shape. Furthermore, the diameter (a dimension in the horizontal direction) of the head 43b can be appropriately changed. The diameter of the head 43b may be smaller than, equal to, or larger than the diameter of the engagement member 44. The shaft 43a extends from the upper surface of the head 43b in the +Z direction along the central axis of the head 43b. The head 43b is in contact with the first connection portion 61 of the bus bar 42 from the −Z direction. A thickness T5 of the head 43b in the Z direction is smaller than the plate thickness T3 of the first connection portion 61. The thickness T5 of the head 43b in the Z direction is smaller than the plate thickness T4 of the base plate 41. The thickness T5 of the head 43b in the Z direction is smaller than a thickness T6 of the heat transfer member 92 in the Z direction. The head 43b is preferably designed to be as thin as possible in the Z direction.

In the present embodiment, the connection component 20 is attached to the fastening member 43 from the Z direction in a state of being previously fixed to the electronic component 10 via the fastening member 72 or the fastening member 71. For example, in the connection component 20, the shaft portion 43a of the fastening member 43 is inserted into the second attachment hole 22h of the second portion 22. The engagement member 44 (for example, a nut) is engaged with the shaft portion 43a of the fastening member 43 protruding from the second attachment hole 22h of the second portion 22 of the connection component 20. The engagement member 44 is attached to the upper end of the shaft 43a in the Z direction, for example. The head 43b of the fastening member 43 and the engagement member 44 press the connection component 20 and the bus bar 42 from both sides in the Z direction. With such engagement, the connection component 20 is fixed to the fastening member 43.

In the present embodiment, the heat transfer member 92 includes a first portion 92a and a second portion 92b. The first portion 92a is disposed between the head 62b and the metal plate 80 in the Z direction and is in contact with the head 62b. The second portion 92b is disposed between the first connection portion 61 and the metal plate 80 in the Z direction and is in contact with the first connection portion 61. The heat transfer member 92 transfers heat from the head 62b toward the metal plate.

The heat transfer member 92 is an elastic sheet having elasticity. Therefore, the head 43b of the fastening member 43 is embedded in the heat transfer member 92 by being pressed against the heat transfer member 92. In other words, the head 43b enters a recessed portion 92c generated by the head 43b being pressed against the heat transfer member 92.

### 8. Advantages

In the electrical connection unit 1 as described above, heat is generated at the connection portion between the conductive members such as the connection component 20 (heat storage member) and the bus bar 42 as the resistance increases. Therefore, it is required to release heat generated at the connection portion between the conductive members to the outside.

Here, as a comparative example, an electrical connection unit in which a bolt for fastening a connection component (heat storage member) and a bus bar is inserted from the outside of a metal plate will be considered. In such a constitution of the comparative example, for example, a heat transfer member disposed between the bus bar and the metal plate cannot be disposed at the attachment position of the bolt. Therefore, heat generated at the connection portion between the connection component and the bus bar may not be successfully released to the metal plate.

On the other hand, in the present embodiment, the electrical connection unit 1 includes the electronic component 10, the metal plate 80, the connection component 20, the bus bar 42, the fastening member 43, and the heat transfer member 92. The metal plate 80 is separated from the electronic component 10 in the Z direction. The connection component 20 is electrically connected to the electronic component 10. The bus bar 42 has the first connection portion 61. The first connection portion 61 is disposed between at least a part of the connection component 20 and the metal plate 80 in the Z direction. The fastening member 43 has the head 43b and the shaft 43a. The head 43b is disposed between the first connection portion 61 and the metal plate 80 in the Z direction. The shaft 43a penetrates the first connection portion 61 in the Z direction and reaches the connection component 20. At least a part of the heat transfer member 92 is disposed between the head 43b and the metal plate 80 in the Z direction and is in contact with the head 43b. The heat transfer member 92 transfers heat from the head 43b toward the metal plate 80.

According to such a constitution, the first connection portion 61 of the bus bar 42 and the head 43b of the fastening member 43 can be brought into contact with each other. Due to such an attachment position of the head 43b, a surface difference (a difference in height in the Z direction) between the first connection portion 61 and the head 43b is reduced. Therefore, the heat transfer member 92 can be disposed between the head 43b and the metal plate 80. With such disposition of the heat transfer member 92, heat is easily transferred from the electronic component 10 and the like to the metal plate 80. Therefore, the heat transfer performance of the electrical connection unit 1 is improved.

In the present embodiment, the heat transfer member 92 includes a first portion 92a and a second portion 92b. The first portion is disposed between the head 43b and the metal plate 80 in the Z direction and is in contact with the head 43b. The second portion 92b is disposed between the first connection portion 61 of the bus bar 42 and the metal plate 80 in the Z direction and is in contact with the first connection portion 61. According to such a constitution, the heat transfer member 92 can be provided over both the bus bar 42 and the fastening member 43. By disposing the heat transfer member 92 as described above, the heat of the bus bar 42 is easily transferred to the metal plate 80 via the heat transfer member 92, and the heat transfer performance is improved.

In the present embodiment, the thickness T5 of the head 43b in the Z direction is smaller than the plate thickness T3 of the first connection portion 61. According to such a constitution, a surface difference between the first connection portion 61 of the bus bar 42 and the head 43b of the fastening member 43 is further reduced, and heat is easily transferred to the metal plate 80. In addition, it is easy to install the heat transfer member 92 over both the bus bar 42 and the fastening member 43.

In the present embodiment, the thickness T5 of the head 43b in the Z direction is smaller than a thickness T6 of the heat transfer member 92 in the Z direction. According to such a constitution, a surface difference between the first connection portion 61 of the bus bar 42 and the head 43b of the fastening member 43 is further reduced, and heat is easily transferred to the metal plate 80. In addition, since the heat transfer member 92 is thicker than the head 43b of the fastening member 43, it is easy to install the heat transfer member 92 over both the bus bar 42 and the fastening member 43.

In the present embodiment, the heat transfer member 92 is a heat transfer sheet having elasticity. According to such a constitution, the heat transfer member 92 can be installed such that the head 43b of the fastening member 43 is buried in the heat transfer member 92. Therefore, since the heat transfer member 92 and the fastening member 43 are brought into close contact with each other, heat transfer performance is improved. Furthermore, an increase in size of the electrical connection unit 1 in the Z direction is curbed. In addition, since the head 43b of the fastening member 43 enters the recessed portion 92c of the heat transfer member 92, a contact location between the head 43b and the heat transfer member 92 does not become unstable.

In the present embodiment, the metal plate 80 is used as an example of a heat dissipation member. The metal plate 80 includes a plate-shaped flat surface portion 81 (base portion) provided in a direction intersecting the Z direction. The heat transfer member 92 is disposed between the head 43b and the flat surface portion 81 of the metal plate 80 in the Z direction. According to such a constitution, heat in the electrical connection unit 1 is favorably released to the outside while a rigidity of the electrical connection unit 1 is secured.

### 9. Modification Examples

Next, several modification examples will be described. Note that a constitution other than those described below in each modification example is the same as the constitution of the embodiment.

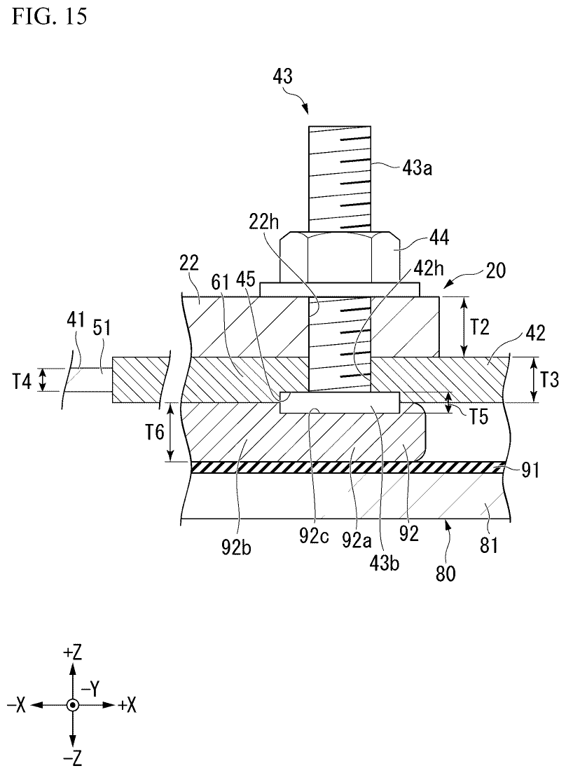

FIG. 15 is an enlarged cross-sectional view illustrating a modification example. FIG. 15 corresponds to the cross-sectional view of FIG. 14. As illustrated in FIG. 15, the head 43b of the fastening member 43 may be partially or entirely embedded in the first connection portion 61 of the bus bar 42 by being caulked and fixed to the bus bar 42. That is, a part or the whole of the head 43b may be disposed in a recessed portion 45 of the lower surface of the bus bar 42, and in this case, a surface difference (a difference in height in the Z direction) between the head 43b and the bus bar 42 is further reduced.

In the above-described embodiment, the metal plate 80 has been described as an example of the heat dissipation member, but the present invention is not limited thereto. The heat dissipation member may be, for example, a resin plate. In addition, the first-type connection component 20M has been described as an example of a first conductive member, and the bus bar 42 has been described as an example of a second conductive member, but the present invention is not limited thereto. The first conductive member may be a conductive member (for example, the second-type connection component 20N, the connection component 30, the bus bar 42, or the coupling bus bar 75) different from the first-type connection component 20M mounted on the heat dissipation member (the metal plate 80 in the present embodiment). The second conductive member may be a conductive member (for example, the connection component 20, the connection component 30, or the coupling bus bar 75) different from the bus bar 42 mounted on the heat dissipation member (the metal plate 80 in the present embodiment). In addition, the first connection portion 61 of the bus bar 42 has been described as an example of a connection portion of the second conductive member, but the present invention is not limited thereto. The connection portion of the second conductive member may be, for example, a portion other than the first connection portion 61 of the bus bar 42, such as the second connection portion 62 of the bus bar 42.

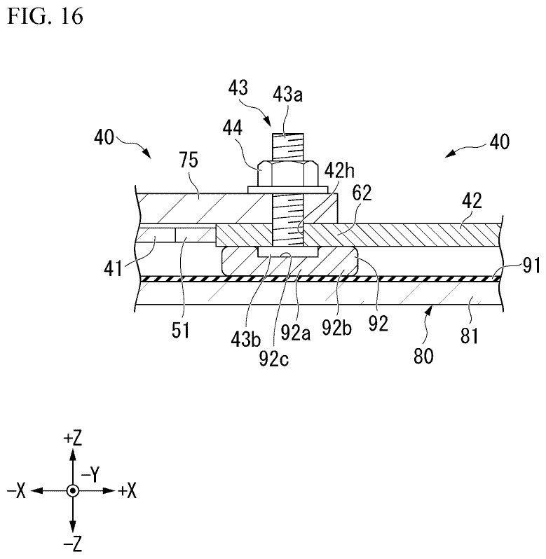

FIG. 16 is an enlarged cross-sectional view illustrating another modification example. As illustrated in FIG. 16, the above-described constitutions of the fastening member 43 and the heat transfer member 92 may be used, for example, for a connection portion between the coupling bus bar 75 and the bus bar 42. As described above, the coupling bus bar 75 is a component that couples two adjacent subunits SU. The coupling bus bar 75 is electrically connected to the electronic component 10 via the bus bar 42, for example. In this case, the coupling bus bar 75 serves as a first conductive member, and the second connection portion 62 of the bus bar 42 serves as a connection portion of a second conductive member. The head 43b of the fastening member 43 is disposed between the second connection portion 62 of the bus bar 42 and the metal plate 80 in the Z direction. The shaft 43a of the fastening member 43 penetrates the second connection portion 62 and reaches the coupling bus bar 75. The heat transfer member 92 has a first portion 92a and a second portion 92b as in the case where the heat transfer member is installed at the coupling location between the connection component 20 and the bus bar 42. The first portion 92a is disposed between the head 43b and the metal plate 80 in the Z direction and is in contact with the head 43b. The second portion 92b is in contact with the second connection portion 62 of the bus bar 42 in the Z direction. The dimensional relationship of the head 43b is similar to that of the above-described embodiment.

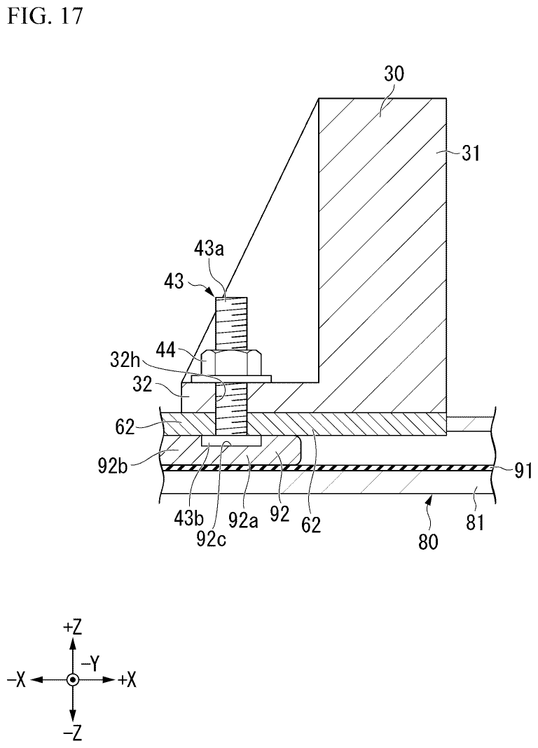

FIG. 17 is an enlarged cross-sectional view illustrating still another modification example. As illustrated in FIG. 17, the above-described constitutions of the fastening member 43 and the heat transfer member 92 may be used, for example, for a connection portion between the connection component 30 for external connection and the bus bar 42. In this case, the connection component 30 serves as a first conductive member, and the second connection portion 62 of the bus bar 42 serves as a connection portion of a second conductive member. The head 43b of the fastening member 43 is disposed between the second connection portion 62 of the bus bar 42 and the metal plate 80 in the Z direction. The shaft 43a of the fastening member 43 penetrates the second connection portion 62 and reaches the connection component 30. The heat transfer member 92 has a first portion 92a and a second portion 92b as in the case where the heat transfer member is installed at a coupling location between the connection component 30 and the bus bar 42. The first portion 92a is disposed between the head 43b and the metal plate 80 in the Z direction and is in contact with the head 43b. The second portion 92b is in contact with the second connection portion 62 of the bus bar 42 in the Z direction. Also in this case, the dimensional relationship of the head 43b is similar to that of the above-described embodiment.

In addition, the constitutions of the fastening member 43 and the heat transfer member 92 described above may be used, for example, for a connection portion between the connection components 20 in addition to the above-described several embodiments and modification examples.

In addition, the base member of the routing board 40 is not limited to the base plate 41 having the plate-shaped flat surface portion 51. The routing board 40 may be a base member (for example, an insulating sheet film) having a sheet-film-shaped flat surface portion 51. In this case, the accommodation portion 55 may be formed by a part of the flat surface portion 51 following the outer shape of the bus bar 42. In the present disclosure, the “sheet-shaped” or “sheet” is not limited to a member having a thickness of 1 mm or more, and a member (so-called a film) having a thickness of less than 1 mm can also be used.

The base plate 41 of the routing board 40 may include a plurality of members (plate members or sheet members). The plurality of members are provided to sandwich the plurality of bus bars 42 arranged in the horizontal direction, for example, from both sides in the Z direction. For example, the plurality of members are integrated by sandwiching the plurality of bus bars 42 through laminate molding, for example. The plurality of members form the flat surface portion 51. In this case, the accommodation portion 55 may be formed in a hollow shape inside the base plate 41 (between the plurality of members). The plurality of members may be a plurality of plate members, a plurality of sheet members, or a combination of a plate member and a sheet member. The sheet member may be, for example, a flexible sheet member. The flat surface portion 51 formed of the plurality of members has an opening through which at least first connection portion 61 and second connection portion 62 of bus bar 42 are exposed. For example, in this case, the accommodation portion 55 formed between the plurality of members corresponds to an example of an “accommodation portion recessed in the first direction (Z direction)”.

Several embodiments and modification examples have been described above. However, the embodiment and the modification examples are not limited to the examples described above. For example, a plurality of embodiments may be implemented in combination with each other. The above-described embodiments can be implemented in various other forms, and various additions, omissions, substitutions, and changes can be made without departing from the concept of the present disclosure.

According to the present disclosure, heat transfer performance can be improved.

REFERENCE SIGNS LIST

| | |
|---|---|
| 1 | Electrical connection unit |
| 10 | Electronic component |
| 20 | Connection component (first conductive member) |
| 42 | Bus bar (second conductive member) |
| 43 | Fastening member |
| 43a | Shaft |
| 43b | Head |
| 61 | First connection portion (connection portion) |
| 80 | Metal plate (heat dissipation member) |
| 81 | Flat surface portion (base portion) |
| 92 | Heat transfer member |
| 92a | First portion |
| 92b | Second portion |

What is claimed is:

1. An electrical connection unit comprising:
an electronic component;
a heat dissipation member that is separated from the electronic component in a first direction;
a first conductive member electrically connected to the electronic component;
a second conductive member having a connection portion disposed between at least a part of the first conductive member and the heat dissipation member in the first direction;
a fastening member having a head disposed between the connection portion and the heat dissipation member in the first direction, and a shaft penetrating the connection portion in the first direction and extending to reach the first conductive member; and
a heat transfer member of which at least a part thereof is disposed between the head and the heat dissipation member in the first direction, and is in contact with the head to transfer heat from the head toward the heat dissipation member.

2. The electrical connection unit according to claim 1, wherein
the heat transfer member includes a first portion disposed between the head and the heat dissipation member in the first direction and in contact with the head, and a second portion disposed between the connection portion and the heat dissipation member in the first direction and in contact with the connection portion.

3. The electrical connection unit according to claim 1, wherein
a thickness of the head in the first direction is smaller than a thickness of the connection portion in the first direction.

4. The electrical connection unit according to claim 1, wherein
a thickness of the head in the first direction is smaller than a thickness of the heat transfer member in the first direction.

5. The electrical connection unit according to claim 1, wherein
the heat transfer member is a heat transfer sheet having elasticity.

6. The electrical connection unit according to claim 1, wherein
the heat dissipation member is a metal plate including a base portion provided in a direction intersecting the first direction and having a plate-shape, and
the heat transfer member is disposed between the head and the base portion of the metal plate in the first direction.
